(19) United States
(12) Patent Application Publication
(10) Pub. No.: US 2025/0133971 A1
(43) Pub. Date: Apr. 24, 2025

(54) SELECTOR, SEMICONDUCTOR DEVICE INCLUDING THE SAME AND METHOD FOR FABRICATING SELECTOR AND SEMICONDUCTOR DEVICE

(71) Applicants: SK hynix Inc., Gyeonggi-do (KR); Kioxia Corporation, Tokyo (JP)

(72) Inventors: Jeong Myeong KIM, Gyeonggi-do (KR); Cha Deok DONG, Gyeonggi-do (KR); Keo Rock CHOI, Gyeonggi-do (KR); Hyungjun CHO, Tokyo (JP); Hyung-Woo AHN, Tokyo (JP)

(21) Appl. No.: 18/783,415

(22) Filed: Jul. 25, 2024

(30) Foreign Application Priority Data
Oct. 20, 2023 (KR) 10-2023-0141523

(51) Int. Cl. H10N 70/00; H10B 63/00; H10N 70/20

(52) U.S. Cl. CPC H10N 70/8845; H10B 63/80; H10N 70/026; H10N 70/043; H10N 70/063; H10N 70/24; H10N 70/841

(57) ABSTRACT

A selector includes a base material including carbon; and a dopant implanted into the base material. A method for fabricating a selector includes forming a carbon layer and implanting a dopant into the carbon layer. A semiconductor device includes a selector pattern including carbon as a base material and a dopant implanted through an ion implantation process; and a memory pattern disposed in an upper portion or a lower portion of the selector pattern.

### CROSS-REFERENCE TO RELATED APPLICATIONS

The present application claims priority under 35 U.S.C. 119(a) to Korean Patent Application No. 10-2023-0141523, filed on Oct. 20, 2023, which is incorporated herein by reference in its entirety.

### BACKGROUND

### 1. Field

Embodiments of the present disclosure relate to a memory circuit or device, and their applications in a semiconductor device.

### 2. Description of the Related Art

Recent demands for miniaturization, low power consumption, high performance, and diversification of electronic devices require semiconductor devices configured to store information in various electronic devices, such as computers and portable communication devices. Researchers and the industry are studying to develop such semiconductor devices. Among the semiconductor devices are those that may store data by taking advantage of the characteristic of switching between different resistance states according to the applied voltage or current, such as a Resistive Random Access Memory (RRAM), a Phase-change Random Access Memory (PRAM), a Ferroelectric Random Access Memory (FRAM), a Magnetic Random Access Memory (MRAM), an E-fuse and the like.

### SUMMARY

Embodiments of the present disclosure are directed to a selector with excellent electrical and physical characteristics by using carbon as a matrix of the selector and ion-implanting a dopant into carbon, a semiconductor device including the selector, and a method for fabricating the semiconductor device.

In accordance with an embodiment of the present disclosure, a selector includes a base material including carbon; and a dopant implanted into the base material.

In accordance with another embodiment of the present disclosure, a method for fabricating a selector includes forming a carbon layer; and implanting a dopant into the carbon layer.

In accordance with another embodiment of the present disclosure, a semiconductor device includes a selector pattern including carbon as a base material and a dopant implanted through an ion implantation process; and a memory pattern disposed in an upper portion or a lower portion of the selector pattern.

In accordance with another embodiment of the present disclosure, a method for fabricating a semiconductor device includes forming a carbon layer over a substrate; forming a selector layer by implanting a dopant through an ion implantation process; forming a memory layer in an upper portion or a lower portion of the selector layer; and forming a memory cell including a memory pattern and a selector pattern by etching the memory layer and the selector layer through an etching process using a mask pattern.

### BRIEF DESCRIPTION OF THE DRAWINGS

FIGS. 1A and 1B illustrate a method for fabricating a selector in accordance with an embodiment of the present disclosure.

FIGS. 2A and 2B illustrate a semiconductor device in accordance with an embodiment of the present disclosure.

FIGS. 3A to 3F illustrate a method for fabricating a semiconductor device in accordance with an embodiment of the present disclosure.

FIGS. 4A to 4F illustrate a method for fabricating a semiconductor device in accordance with another embodiment of the present disclosure.

### DETAILED DESCRIPTION

Various embodiments of the present disclosure will be described below in more detail with reference to the accompanying drawings. The embodiments may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

Hereinafter, the various embodiments of the present disclosure will be described in detail with reference to the attached drawings.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

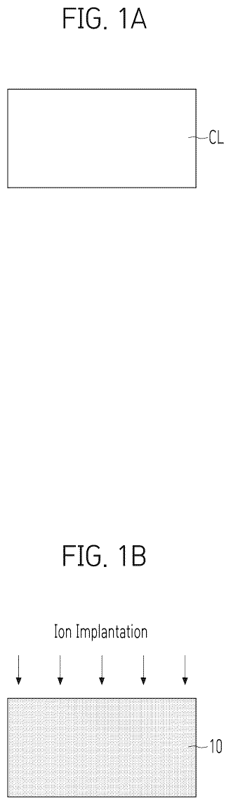

FIGS. 1A and 1B illustrate a method for fabricating a selector in accordance with an embodiment of the present disclosure.

In the embodiment of FIGS. 1A and 1B, only a method for fabricating a selector is illustrated, and descriptions of the structures other than the selector disposed in upper and lower portions of the selector are omitted.

Referring to FIG. 1A, a carbon layer CL may be formed.

The carbon layer CL may serve as a matrix that forms the base of a selector. The carbon layer CL may be of an amorphous phase that may easily involve in a chemical reaction, and when dopants such as arsenic (As) are ion-implanted, new structural bonds may be easily formed, and the metallic states of the dopants may be maintained well. Therefore, the ion-implanted dopants may be able to form the trap sites of conductive carriers more easily and efficiently, thereby effectively realizing the threshold switching operation characteristics of the selector. Also, since the carbon layer CL has low density and high thermal conductivity, the selector based on the carbon layer CL may have excellent electrical and physical characteristics.

The carbon layer CL may be formed by depositing carbon (C) using a physical deposition method e.g., a sputtering method.

According to one embodiment of the present disclosure, the carbon layer CL may include carbon (C) atoms as the major component, and further include at least one of nitrogen (N) atoms, oxygen (O) atoms, and hydrogen (H) atoms. In an embodiment, at least one of nitrogen (N) atoms, oxygen (O) atoms, and hydrogen (H) atoms may be doped onto the carbon layer CL by performing a carbon (C) deposition process in a gas atmosphere of at least one of nitrogen gas, oxygen gas, and hydrogen gas.

Referring to FIG. 1B, the selector 10 may be formed by implanting dopants into the carbon layer CL. For example, ion implantation may be used for the implanting of the dopants into the carbon layer CL.

The dopants may form trap sites of conductive carriers, allowing the selector 10 to perform a threshold switching operation.

The dopants may include, for example, at least one of arsenic (As), phosphorus (P), and antimony (Sb).

According to the illustrated embodiment of FIG. 1B of the present disclosure, the dopants may be implanted using an ion implantation process, however, the disclosure may not be limited by the method used for the implantation of the dopants and other suitable methods may be used without departing from the scope of the present disclosure.

According to an embodiment of the present disclosure, the thickness of the selector 10 may be the same as the thickness of the carbon layer CL. According to another embodiment of the present disclosure, the thickness of the selector 10 may be smaller than the thickness of the carbon layer CL. This is because a portion of the upper portion of the carbon layer CL may be lost due to the damage that may occur during the ion implantation process.

The selector 10 according to an embodiment may include amorphous carbon (C) as the major component, and dopants may be implanted in the selector 10 through the ion implantation process. Also, the selector 10 may optionally further include at least one of nitrogen (N), oxygen (O), and hydrogen (H) in addition to carbon (C). The dopants may include at least one of arsenic (As), phosphorus (P), and antimony (Sb).

Unlike conventional doped nitride or oxide-based selectors, the selector 10 according to the embodiment of the present disclosure may include carbon (C) of an amorphous phase that is ready to involve in a chemical reaction as the major component, and dopants that are implanted using the ion implantation process. When dopants such as arsenic (As) are ion-implanted, the amorphous carbon may form defects and/or vacancies in the selector 10 and the metallic states of the formed dopants may be maintained well, forming the trap sites of conductive carriers more easily and efficiently. In an embodiment, the electrical characteristics of the selector 10 may be further improved. Also, the physical characteristics of the selector 10 may be improved based on the essential characteristics of carbon, which is the major component. When the selector 10 further includes at least one of nitrogen (N), oxygen (O), and hydrogen (H) in addition to carbon (C), the carbon and the additional elements may form various phases, further increasing the formation of defects and/or vacancies in the selector 10. Therefore, by controlling the degree of defects and/or vacancies formation, the desired electrical and/or physical characteristic for the target selector 10 can be achieved.

The selector 10 according to the illustrated embodiment of the present disclosure may include carbon (C) as a base material, and at least one of nitrogen (N), oxygen (O), and hydrogen (H) in addition to the carbon (C). It has been found that the addition of dopants using ion-implantation into the base material, provides excellent electrical and physical characteristics to the selector 10.

The selector 10 according to an embodiment of the present disclosure may be a current adjustment layer configured to control a flow of a current. For example, the selector 10 may reduce and/or suppress leakage current between the memory elements of a semiconductor device. For example, the selector 10 may be formed to have threshold switching characteristics, which hold a current to scarcely flow when the applied voltage is less than a predetermined threshold value, and let the current flow to increase drastically when the applied voltage is equal to or higher than the predetermined threshold value. This threshold value may be called a threshold voltage, and the selector 10 may be realized in a turn-on state or a turn-off state based on the threshold voltage.

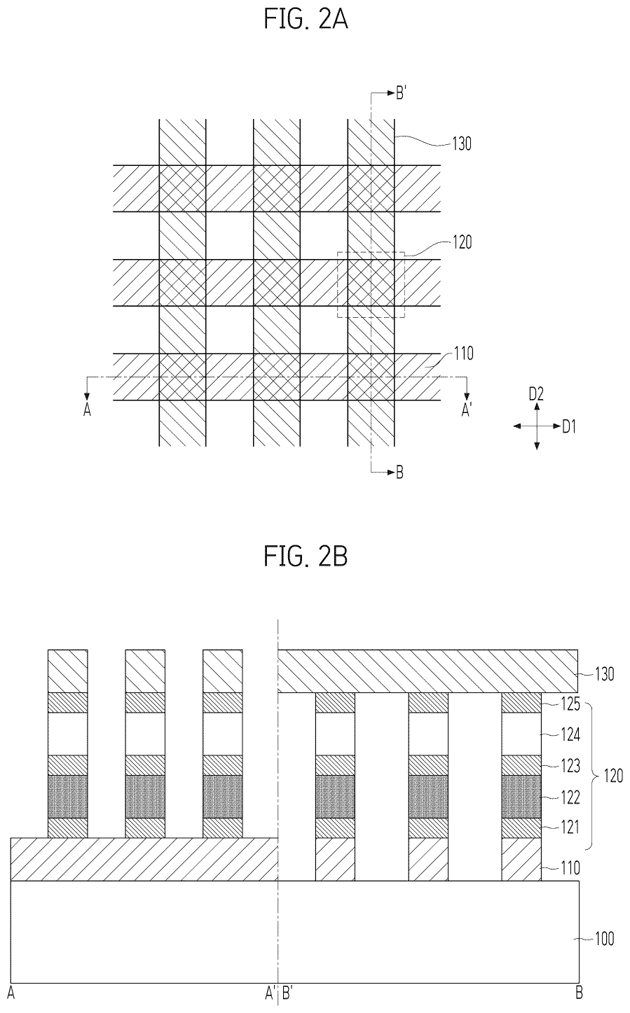

The selector 10 according to an embodiment of the present disclosure may be implemented as a selector layer of a memory cell having a structure in which the selector layer and a memory layer are stacked in the upper and lower portions of a device as described in more detail with reference to FIGS. 2A and 2B.

FIGS. 2A and 2B illustrate a semiconductor device in accordance with an embodiment of the present disclosure. Detailed description of any constituent elements of FIGS. 2A and 2B which are also appearing in FIGS. 1A and 1B, may be omitted to avoid unnecessary repetitive description.

Referring to FIGS. 2A and 2B, the semiconductor device in accordance with an embodiment of the present disclosure may have a cross-point structure which includes a first conductive line 110 formed over a substrate 100 and extending in a first direction (D1), a second conductive line 130 disposed over the first conductive line 110 and extending in a second direction (D2) that intersects with the first direction (D1), and a memory cell 120 disposed at the cross-point between the first conductive line 110 and the second conductive line 130. In the illustrated embodiment of FIG. 2A and FIG. 2B a plurality of memory cells 120, a plurality of first conductive lines 110, and a plurality of second conductive lines 130 are shown, with the plurality of the first and second conductive lines 110 and 130, forming a plurality of cross points. In the embodiment of FIG. 2A and FIG. 2B, it is further shown that a memory cell 120 is disposed at each of the plurality of the cross-points formed between the first conductive lines 110 and the second conductive lines 130.

The substrate 100 may be any suitable semiconductor substrate. For example, the substrate 100 may include a semiconductor material, for example, silicon. At least one structure (not shown) may be formed in the substrate 100. For example, a lower structure may include a driving circuit (not shown) that is electrically connected to control the first conductive line 110 and/or the second conductive line 130 formed over the substrate 100.

The first conductive line 110 and the second conductive line 130 may be coupled to the memory cell 120 and drive the memory cell 120 by transferring a voltage or current to the memory cell 120. Either the first conductive lines 110 or the second conductive lines 130 may be word lines. For example, the first conductive lines 110 may be word lines and then the second conductive lines may be bit lines, or vice versa the first conductive lines 110 may be bit lines and the second conductive lines may be word lines. Each of the first conductive lines 110 and the second conductive lines 130 may have a single-layer structure. Each of the first conductive lines 110 and the second conductive lines 130 may have a multi-layer structure. Each of the first conductive lines 110 and the second conductive lines 130 may have a single-layer structure or a multi-layer structure and may include a conductive material. The conductive material may include metals, metal nitrides, conductive carbon materials, and combinations thereof. For example, each of the first conductive line 110 and the second conductive line 130 may include tungsten (W), titanium (Ti), tantalum (Ta), platinum (Pt), aluminum (Al), copper (Cu), zinc (Zn), nickel (Ni), cobalt (Co), lead (Pd), tungsten nitride (WN), tungsten silicide (WSi), titanium nitride (TIN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SIC), silicon carbon nitride (SiCN), or a combination thereof.

The memory cells 120 may be arranged in a matrix form in the first direction (D1) and the second direction (D2) to overlap with the intersection areas of the first conductive lines 110 and the second conductive lines 130. Each of the memory cells 120 may have a size that is equal to or smaller than the corresponding intersection area of a corresponding pair of a first and a second conductive line 110 and 130. In an embodiment, each of the memory cells 120 may have a size that is greater than the corresponding intersection area of a corresponding pair of a first and a second conductive line 110 and 130.

The memory cell 120 may have a cylindrical shape. The memory cell 120 may have a square pillar shape. However, the shape of the memory cell may not be limited thereto.

The space between the first conductive lines 110, the second conductive lines 130, and the memory cells 120 may be filled with a dielectric material (not shown).

The memory cell 120 may include a stacked structure including a selector pattern 122. For example, the memory cell 120 may include a lower electrode 121, a selector pattern 122, a middle electrode 123, a memory pattern 124, and an upper electrode 125.

The selector pattern 122 shown in FIG. 2B may correspond to the selector 10 shown in FIG. 1B. As for what is similar to the above-described embodiment of FIG. 1B, a detailed description of it may be omitted in this embodiment of the present disclosure.

The lower electrode 121 may be formed to be the lowermost portion of the memory cell 120. The lower electrode 121 may be electrically connected to the first conductive line 110, and may thus form a transfer path for current or voltage between the first conductive line 110 and the memory cell 120. The middle electrode 123 may be disposed between the selector pattern 122 and the memory pattern 124, and may serve to electrically connect them to each other while physically separating them from each other. The upper electrode 125 may form an uppermost portion of the memory cell 120 and may thus form a transfer path for current or voltage between the second conductive line 130 and the memory cell 120.

The lower, the middle, and the upper electrodes 121, 123, and 125 may have a single-layer structure or a multi-layer structure including various conductive materials, such as a metal, a nitride, a silicide-based material, and a combination thereof. For example, the lower, the middle, and the upper electrodes 121, 123, and 125 may include tungsten (W), titanium (Ti), tantalum (Ta), platinum (Pt), aluminum (Al), copper (Cu), zinc (Zn), nickel (Ni), cobalt (Co), lead (Pd), chromium (Cr), tungsten nitride (WN), tungsten silicide (WSi), titanium silicide (TiSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), or a combination thereof.

The lower, the middle, and the upper electrodes 121, 123, and 125 may be formed of the same material or different materials.

The lower, middle, and upper electrodes 121, 123, and 125 may have the same thickness or different thicknesses.

At least one of the lower, the middle, and the upper electrodes 121, 123, and 125 may be selectively omitted. For example, when the lower electrode 121 is omitted, the first conductive line 110 may perform a function of the lower electrode 121 instead of the omitted lower electrode 121. When the upper electrode 125 is omitted, the second conductive line 130 may perform a function of the upper electrode 125 instead of the omitted upper electrode 125.

The selector pattern 122 may be a current adjustment layer which is configured to control flow of current, and prevent current leakage that may occur between the memory cells 121 that share the first conductive line 110 or the second conductive line 130. The selector pattern 122 may have threshold switching characteristics, which hold current to scarcely flow when the applied voltage is lower than the predetermined threshold value and let the current flow to increase drastically when the applied voltage is equal to or higher than the predetermined threshold value. This threshold value may be called a threshold voltage, and the selector pattern 122 may be realized in a turn-on state or a turn-off state based on the threshold voltage.

Unlike the conventional doped nitride or oxide-based selector, the selector pattern 122 may include amorphous carbon (C), which is the major component, and a dopant, which is implanted through the ion implantation process. Also, the selector pattern 122 may further include at least one of nitrogen (N), oxygen (O), and hydrogen (H) in addition to the carbon (C). The dopants may include at least one of arsenic (As), phosphorus (P), and antimony (Sb).

The selector pattern 122 may include carbon (C) of an amorphous phase, which may easily involve in a chemical reaction, as the major component, and may include dopants which are implanted through an ion implantation process, forming defects and/or vacancies in the selector pattern 122. Accordingly, the metallic states of the dopants may be maintained well, which allows them to form trap sites of conductive carriers more easily and efficiently. This may further improve the electrical characteristics of the selector pattern 122. Also, the physical characteristics of the selector pattern 122 may be improved due to the essential characteristics of carbon, which is the major component. When the selector pattern 122 further includes at least one of nitrogen (N), oxygen (O), and hydrogen (H) in addition to carbon (C), the carbon (C) and the additional element may form various phases, which may further increase the extent of forming defects and/or vacancies in the selector pattern 122. Therefore, it is possible to control the extent of forming defects and/or vacancies in the selector pattern 122 by comprehensively considering the physical and electrical characteristics required for the target selector pattern 122.

The selector pattern 122 according to an embodiment of the present disclosure may include carbon (C) as a base material, and the selector pattern 122 may include at least one of nitrogen (N), oxygen (O), and hydrogen (H) in addition to the carbon (C), exhibiting excellent electrical and physical characteristics by ion-implanting dopants into the base material.

The memory pattern 124 may store different data by switching between different resistance states according to the voltage or current that is applied through the upper and lower portions. The memory pattern 124 may include a material used in a Resistive Random Access Memory (RRAM), a Phase-change Random Access Memory (PRAM), a Ferroelectric Random Access Memory (FRAM), a Magnetic Random Access Memory (MRAM) and the like, for example, a material having variable resistance characteristics used in an RRAM, a PRAM, an FRAM, an MRAM and the like. The memory pattern 124 may include a transition metal oxide used in an RRAM, a PRAM, an FRAM, an MRAM and the like, a metal oxide such as a perovskite-based material, a phase-change material such as a chalcogenide-based material, a ferroelectric material, a ferromagnetic material, and the like.

For example, the memory pattern 124 may include a magnetic tunnel junction (MTJ) structure that includes a free layer with a changeable magnetization direction, a fixed layer with a fixed magnetization direction, and a tunnel barrier layer interposed between the free layer and the fixed layer.

The free layer may be a layer configured to store different data by having a changeable magnetization direction, and it may also be called a storage layer. The free layer may have one of different magnetization directions, or one of different electron spin directions, thereby switching the polarity of the free layer in the MTJ structure and changing the resistance value. According to some embodiments of the present disclosure, the polarity of the free layer may be changed or inversed when a voltage or current signal (e.g., a driving current which is equal to or higher than a predetermined threshold value) is applied to the MTJ structure. As the polarity of the free layer changes, the free layer and the fixed layer may have different magnetization directions or different electron spin directions. Therefore, the memory pattern 124 may store different data or represent different data bits. The magnetization direction of the free layer may vary between a top-down direction and a bottom-up direction. This change in the magnetization direction of the free layer may be induced by a spin transfer torque which is generated based on the applied current or voltage.

The fixed layer may have a fixed magnetization direction, which does not change while the magnetization direction of the free layer changes. The fixed layer may also be called a reference layer. According to some embodiments of the present disclosure, the fixed layer may be fixed to a magnetization direction from top to bottom. According to some embodiments of the present disclosure, the fixed layer may be fixed to a magnetization direction from bottom to top.

The free layer and the fixed layer may have a single-layer structure or a multi-layer structure including a ferromagnetic material. For example, the free layer and the fixed layer may include alloys including Fe, Ni, or Co as the major component, such as Fe—Pt alloy, Fe—Pd alloy, Co—Pd alloy, Co—Pt alloy, Fe—Ni—Pt alloy, Co—Fe—Pt alloy, Co—Ni—Pt alloy, Co—Fe—B alloy and the like, or may include a stacked structure formed of metals, for example, a stacked structure such as Co/Pt, Co/Pd and the like.

The tunnel barrier layer may enable tunneling of electrons in both a data read operation and a data write operation. The tunnel barrier layer may include a dielectric oxide, such as MgO, CaO, SrO, TiO, VO, NbO, Al₂O₃, TiO₂, Ta₂O₅, RuO₂, B₂O₃ and the like.

The memory pattern 124 may have a single-layer structure or may have a multi-layer structure that exhibits variable resistance characteristics by combining two or more layers. However, the embodiments of the present disclosure are not limited to it, and the memory cell 120 may include other memory layers that may store different data in various ways, instead of the memory pattern 124.

According to an embodiment of the present disclosure, the memory cell 120 may include the lower electrode 121, the selector pattern 122, the middle electrode 123, the memory pattern 124, and the upper electrode 125 that are sequentially stacked. However, the memory cell 120 may be modified variously as long as it has data storage characteristics. For example, at least one of the middle electrode 123 and the upper electrode 125 may be omitted. Also, the positions of the selector pattern 122 and the memory pattern 124 may be switched with each other. Also, the memory cell 120 may further include one or more layers (not shown) to improve the characteristics of the memory cell 120 in addition to the layers 121, 122, 123, 124, and 125 or to improve the process. For example, it may further include at least one of a lower electrode contact and an upper electrode contact. Also, for example, a hard mask pattern may remain.

The memory cells 120 formed as above may be disposed spaced apart from each other at regular intervals, and a trench may be formed between them. The trench between the memory cells 120 may have a height-to-width (H/W) aspect ratio in the range of, for example, approximately 1:1 to 40:1, or approximately 10:1 to 40:1, or approximately 10:1 to 20:1, or approximately 5:1 to 10:1, or approximately 10:1 to 15:1, or approximately 1:1 to 25:1, or approximately 1:1 to 30:1, or approximately 1:1 to 35:1, or approximately 1:1 to 45:1, or approximately 1:1 to 40:1.

According to some embodiments of the present disclosure, these trenches may have sidewalls that are substantially perpendicular to the upper surface of the substrate 100. Also, according to one embodiment of the present disclosure, the neighboring trenches may be spaced apart from each other by substantially the same distance. However, according to another embodiment of the present disclosure, the space between the neighboring trenches may vary.

Although the cross-point structure having a single memory cell 120 is described in this embodiment of the present disclosure, the cross-point structure may include two or more memory cells 120 that are stacked in the vertical direction.

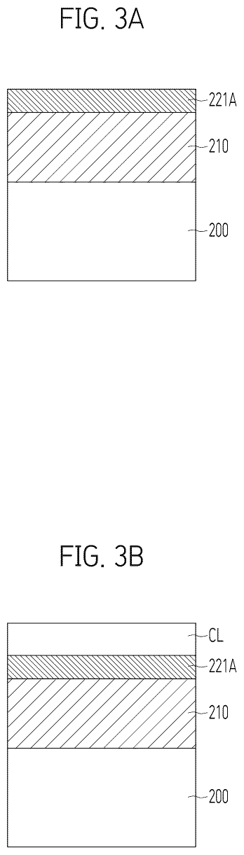

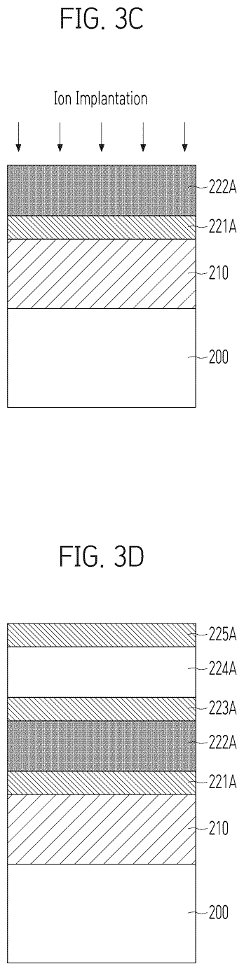

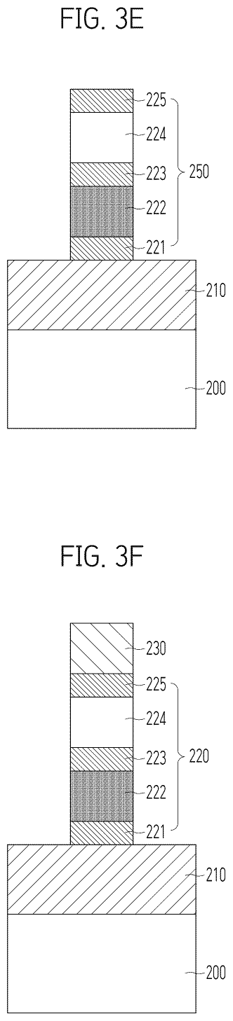

Subsequently, a method for fabricating a semiconductor device in accordance with an embodiment of the present disclosure will be described with reference to FIGS. 3A to 3F. In the following description, a lower electrode layer 221A, a selector layer 222A, a middle electrode layer 223A, a memory layer 224A, and an upper electrode layer 225A may represent material layers that are to be formed into a lower electrode 221, a selector pattern 222, a middle electrode 223, a memory pattern 224, and an upper electrode 225 through a patterning process, respectively.

Referring to FIG. 3A, a first conductive line 210 may be formed over a substrate 200 where a predetermined lower structure (not shown) is formed. The first conductive line 210 may be formed by forming a conductive layer for forming the first conductive line 210 over the substrate 200 and then etching the conductive layer using a line-shaped mask pattern that extends in the first direction (D1). The first conductive line 210 may have a single-layer structure or a multi-layer structure including a conductive material. Non-limiting examples of the conductive material may include metals, metal nitrides, conductive carbon materials, and combinations thereof.

A lower electrode layer 221A may be formed over the first conductive line 210. The lower electrode layer 221A may have a single-layer structure or a multi-layer structure including various conductive materials, such as a metal, a nitride, a silicide-based material, and a combination thereof.

Referring to FIG. 3B, a carbon layer CL may be formed over the lower electrode layer 221A.

The carbon layer CL may serve as a matrix forming the base of the selector. The carbon layer CL may be formed of an amorphous phase, which may easily involve in a chemical reaction, and when dopants such as arsenic (As) are ion-implanted, new structural bonds may be easily formed and the metallic states of the dopants may be maintained well. Since the ion-implanted dopants are configured to form the trap sites of the conductive carriers more easily and efficiently, the threshold switching operation characteristics of the selector may be effectively realized. Also, since the carbon layer CL has low density and high thermal conductivity, the selector based on the carbon layer CL may have excellent electrical and physical characteristics.

A carbon layer CL may be formed by depositing carbon (C) through a physical deposition method, for example, a sputtering method.

According to one embodiment of the present disclosure, the carbon layer CL may include carbon (C) atoms as the major component, and the carbon layer CL may further include at least one of nitrogen (N) atoms, oxygen (O) atoms, and hydrogen (H) atoms. In an embodiment, the at least one of nitrogen (N) atoms, oxygen (O) atoms, and hydrogen (H) atoms may be doped onto the carbon layer CL by performing the carbon (C) deposition process in a gas atmosphere of at least one of nitrogen gas, oxygen gas, and hydrogen gas.

Referring to FIG. 3C, dopants may be implanted into the carbon layer CL to form the selector layer 222A.

The dopants may form trap sites of conductive carriers, allowing the finally formed selector pattern 222 to perform a threshold switching operation.

The dopants may include, for example, at least one of arsenic (As), phosphorus (P), and antimony (Sb).

According to one embodiment of the present disclosure, the dopants may be implanted through an ion implantation process.

According to one embodiment of the present disclosure, the thickness of the selector layer 222A may be the same as the thickness of the carbon layer CL. According to another embodiment of the present disclosure, the thickness of the selector layer 222A may be smaller than the thickness of the carbon layer CL. This is because a portion of the upper portion of the carbon layer CL may be lost due to the damage that may occur during the ion implantation process.

Referring to FIG. 3D, a middle electrode layer 223A may be formed over the selector layer 222A. The middle electrode layer 223A may have a single-layer structure or a multi-layer structure including various conductive materials, such as a metal, a nitride, a silicide-based material, and a combination thereof.

A memory layer 224A may be formed over the middle electrode layer 223A. The memory layer 224A may be formed of a material that is used in an RRAM, a PRAM, an FRAM, an MRAM and the like, for example, a material having variable resistance characteristics used in an RRAM, a PRAM, an FRAM, an MRAM and the like. According to one embodiment of the present disclosure, the memory layer 224A may include a transition metal oxide used in an RRAM, a PRAM, an FRAM, an MRAM and the like, a metal oxide such as a perovskite-based material, a phase-change material such as a chalcogenide-based material, a ferroelectric material, a ferromagnetic material, and the like. According to another embodiment of the present disclosure, the memory layer 224A may have a magnetic tunnel junction (MTJ) structure that includes a free layer with a changeable magnetization direction, a fixed layer with a fixed magnetization direction, and a tunnel barrier layer interposed between the free layer and the fixed layer.

An upper electrode layer 225A may be formed over the memory layer 224A. The upper electrode layer 225A may have a single-layer structure or a multi-layer structure including various conductive materials, such as a metal, a nitride, a silicide-based material, and a combination thereof.

Referring to FIG. 3E, a memory cell 220 is illustrated where a lower electrode 221, a selector pattern 222, a middle electrode 223, a memory pattern 224, and an upper electrode 225 are sequentially stacked and formed by using a mask pattern as an etch mask and sequentially etching the upper electrode layer 225A, the memory layer 224A, the middle electrode layer 223A, the selector layer 222A, and the lower electrode layer 221A.

Referring to FIG. 3F, a second conductive line 230 may be formed over the upper electrode 225. The second conductive line 230 may be formed by depositing a conductive layer for forming the second conductive line 230 and etching the conductive layer using a line-shaped mask pattern that extends in the second direction (D2).

Through the above process, the semiconductor device illustrated in FIG. 3F may be formed.

The semiconductor device according to an embodiment of the present disclosure may include the first conductive line 210, the memory cell 220, and the second conductive line 230 that are sequentially formed over the substrate 200. The memory cell 220 may include the lower electrode 221, the selector pattern 222, the middle electrode 223, the memory pattern 224, and the upper electrode 225 that are sequentially formed.

Unlike the conventional doped nitride or oxide selector, the selector pattern 222 may include amorphous carbon (C) which is the major component, and dopants which are ion-implanted. Also, the selector pattern 222 may optionally further include at least one of nitrogen (N), oxygen (O), and hydrogen (H) in addition to the carbon (C). The dopants may include at least one of arsenic (As), phosphorus (P), and antimony (Sb).

The selector pattern 222 may include carbon (C) of an amorphous phase that may easily involve in a chemical reaction as the major component, and when dopants such as arsenic (As) are ion-implanted, defects and/or vacancies may be formed in the selector pattern 222. Accordingly, the metallic states of the dopants may be maintained well, and the trap sites of conductive carriers may be formed more easily and efficiently. As a result, the electrical characteristics of the selector pattern 222 may be further improved. Also, the physical characteristics of the selector pattern 222 may be improved due to the essential characteristics of carbon, which is the major component. When the selector pattern 222 further includes at least one of nitrogen (N), oxygen (O), and hydrogen (H) in addition to carbon (C), the carbon (C) and the additional element may form various phases, further increasing the extent of forming defects and/or vacancies in the selector pattern 222. Therefore, the extent of forming defects and/or vacancies in the selector pattern 222 may be controlled by comprehensively considering the physical and electrical characteristics required for the target selector pattern 222.

The flatness of the selector pattern 222 is very important for stable crystallization of the memory pattern 222 when the memory pattern 124 in the upper portion is formed. Since the roughness characteristics of the selector pattern 222 according to an embodiment of the present disclosure is improved as the carbon and the additional elements inside form various phases, the memory pattern 224 may be crystallized more stably.

The substrate 200, the first conductive line 210, the memory cell 220, the second conductive line 230, the lower electrode 221, the selector pattern 222, the middle electrode 223, the memory pattern 224, and the upper electrode 225 illustrated in FIG. 3F may respectively correspond to the substrate 100, the first conductive line 110, the memory cell 120, the second conductive line 130, the lower electrode 121, the selector pattern 122, the middle electrode 123, the memory pattern 124, and the upper electrode 125 illustrated in FIG. 2B.

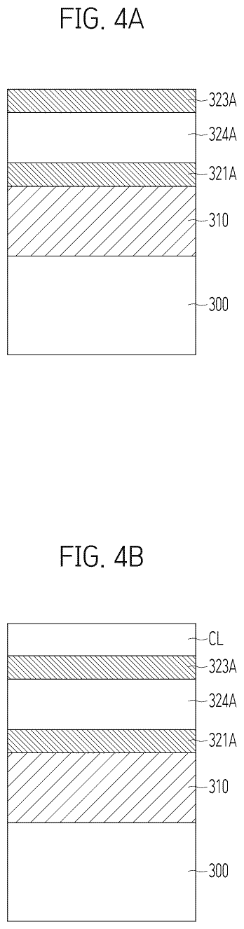

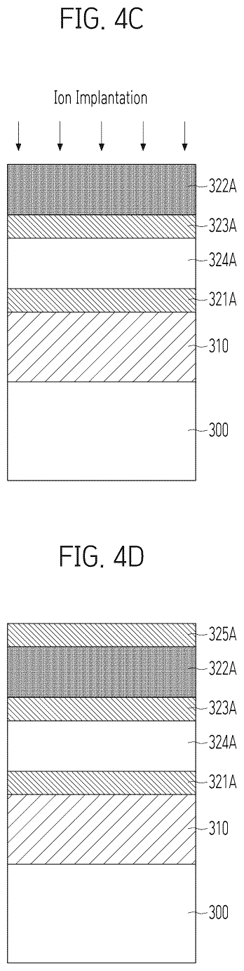

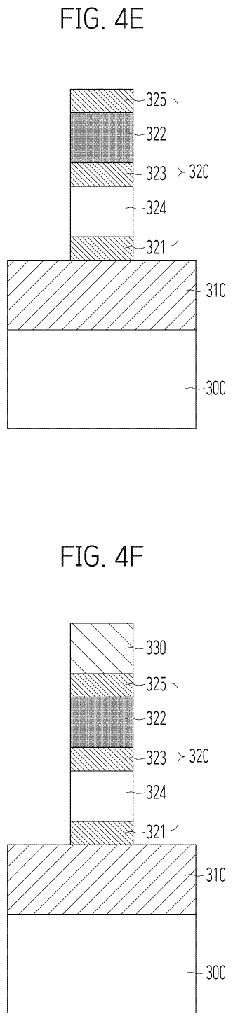

According to an embodiment of the present disclosure, the selector pattern 222 may be formed in the lower portion of the memory pattern 224. However, the relative positions of the selector pattern 222 and the memory pattern 224 may be switched with each other. This will be described below with reference to FIGS. 4A to 4F.

FIGS. 4A to 4F illustrate a method for fabricating a semiconductor device in accordance with another embodiment of the present disclosure. The description will focus on the differences from the embodiments illustrated in FIGS. 1A and 1B, FIGS. 2A and 2B, and FIGS. 3A to 3F. In the following description, a lower electrode layer 321A, a selector layer 322A, a middle electrode layer 323A, a memory layer 324A, and an upper electrode layer 325A may represent material layers that are to be formed into a lower electrode 321, a selector pattern 322, a middle electrode 323, a memory pattern 324, and an upper electrode 325 through patterning processes.

Referring to FIG. 4A, a first conductive line 310 may be formed over a substrate 300 in which a predetermined lower structure (not shown) is formed. The first conductive line 310 may be formed by forming a conductive layer for forming the first conductive line 210 over the substrate 300 and then etching the conductive layer using a line-shaped mask pattern which extends in the first direction (D1).

A lower electrode layer 321A may be formed over the first conductive line 310. The lower electrode layer 321A may have a single-layer structure or a multi-layer structure including various conductive materials, such as a metal, a nitride, a silicide-based material, and a combination thereof.

A memory layer 324A may be formed over the lower electrode layer 321A. The memory layer 324A may be formed of a material used in an RRAM, a PRAM, an FRAM, an MRAM and the like, for example, a material having variable resistance characteristics used in an RRAM, a PRAM, an FRAM, an MRAM and the like.

A middle electrode layer 323A may be formed over the memory layer 324A. The middle electrode layer 323A may have a single-layer structure or a multi-layer structure including various conductive materials, such as a metal, a nitride, a silicide-based material, and a combination thereof.

Referring to FIG. 4B, a carbon layer CL may be formed over the middle electrode layer 323A. The carbon layer CL may be formed by depositing carbon (C) through a physical deposition method, for example, physical vapor deposition or sputtering.

According to one embodiment of the present disclosure, the carbon layer CL may include carbon (C) atoms as the major component, and it may further include at least one of nitrogen (N) atoms, oxygen (O) atoms, and hydrogen (H) atoms in addition to carbon (C). In this case, the at least one of the nitrogen (N) atoms, oxygen (O) atoms, and hydrogen (H) atoms may be doped onto the carbon layer CL by performing a carbon (C) deposition process in the gas atmosphere of at least one of nitrogen gas, oxygen gas, and hydrogen gas.

Referring to FIG. 4C, dopants may be implanted into the carbon layer CL to form the selector layer 322A.

The dopants may form trap sites of conductive carriers, allowing the finally formed selector pattern 322 to perform a threshold switching operation.

For example, the dopants may include at least one of arsenic (As), phosphorus (P), and antimony (Sb).

According to one embodiment of the present disclosure, the dopants may be implanted through an ion implantation process.

According to one embodiment of the present disclosure, the thickness of the selector layer 322A may be the same as the thickness of the carbon layer CL. According to another embodiment of the present disclosure, the thickness of the selector layer 322A may be smaller than the thickness of the carbon layer CL. This is because a portion of the upper portion of the carbon layer CL may be lost due to the damage that may occur during the ion implantation process.

Referring to FIG. 4D, an upper electrode layer 325A may be formed over the selector layer 322A. The upper electrode layer 323A may have a single-layer structure or a multi-layer structure including various conductive materials, such as a metal, a nitride, a silicide-based material, and a combination thereof.

Referring to FIG. 4E, the upper electrode layer 325A, the selector layer 322A, the middle electrode layer 323A, the memory layer 324A, and the lower electrode layer 321A may be sequentially etched by using the mask pattern as an etch barrier. As a result, a memory cell 320 in which the lower electrode 321, the memory pattern 324, the middle electrode 323, the selector pattern 322, and the upper electrode 325 are sequentially stacked may be formed.

Referring to FIG. 4F, a second conductive line 330 may be formed over the upper electrode 325. The second conductive line 330 may be formed by depositing a conductive layer for forming the second conductive line 330 and etching the conductive layer using a line-shaped mask pattern which extends in the second direction (D2).

Through the above process, the semiconductor device illustrated in FIG. 4F may be formed.

The semiconductor device according to the embodiment of the present disclosure may include the first conductive line 310, the memory cell 320, and the second conductive line 330 that are sequentially formed over the substrate 300. The memory cell 320 may include the lower electrode 321, the memory pattern 324, the middle electrode 323, the selector pattern 322, and the upper electrode 325 that are formed sequentially.

Unlike the conventional doped nitride or oxide selectors, the selector pattern 322 may include amorphous carbon (C), which is the major component, and a dopant, which is ion-implanted. Also, the selector pattern 322 may optionally further include at least one of nitrogen (N), oxygen (O), and hydrogen (H) in addition to the carbon (C). The dopants may include at least one of arsenic (As), phosphorus (P), and antimony (Sb).

The selector pattern 322 according to an embodiment of the present disclosure may include carbon (C) and may further include at least one of nitrogen (N), oxygen (O), and hydrogen (H), and include dopants which are ion-implanted, thereby forming defects and/or vacancies due to the various phases that are formed in the selector pattern 322. As a result, the metallic states of the dopants may be maintained well, and the trap sites of conductive carriers may be formed more easily and efficiently. Therefore, the selector pattern 322 according to the embodiment of the present disclosure may exhibit excellent electrical and physical characteristics.

The substrate 300, the first conductive line 310, the memory cell 320, the second conductive line 330, the lower electrode 321, the selector pattern 322, the middle electrode 323, the memory pattern 324, and the upper electrode 325 illustrated in FIG. 4F may respectively correspond to the substrate 200, the first conductive line 210, the memory cell 220, the second conductive line 230, the lower electrode 221, the selector pattern 222, the middle electrode 223, the memory pattern 224 and the upper electrode 225 illustrated in FIG. 3F, and the substrate 100, the first conductive line 110, the memory cell 120, the second conductive line 130, the lower electrode 121, the selector pattern 122, the middle electrode 123, the memory pattern 124, and the upper electrode 125 illustrated in FIG. 2B.

According to an embodiment of the present disclosure, provided are a selector having excellent electrical and physical characteristics by using carbon as a matrix of the selector and ion-implanting a dopant into the carbon matrix, a semiconductor device including the selector, and a method for fabricating the semiconductor device.

While the embodiments of the present disclosure have been described with respect to specific embodiments, it will be apparent to those skilled in the art that various changes and modifications may be made without departing from the spirit and scope of the present disclosure as defined in the following claims. Furthermore, the embodiments may be combined to form additional embodiments.

What is claimed is:

1. A method for fabricating a selector, the method comprising:
forming a carbon layer; and
implanting a dopant into the carbon layer.

2. The method of claim 1, wherein forming the carbon layer includes a physical deposition process, and implanting the dopant includes performing an ion implantation process.

3. The method of claim 1, wherein forming the carbon layer is performed in a gas atmosphere of at least one of nitrogen gas, oxygen gas, and hydrogen gas.

4. The method of claim 1, wherein forming the carbon layer is performed to form an amorphous carbon layer.

5. The method of claim 1, wherein the ion implantation process is performed using a dopant including at least one of arsenic (As), phosphorus (P), and antimony (Sb).

6. The method of claim 1, wherein a defect or vacancy is formed in the selector.

7. A method for fabricating a semiconductor device, the method comprising:
forming a carbon layer over a substrate;
forming a selector layer by implanting a dopant through an ion implantation process;
forming a memory layer in an upper portion or a lower portion of the selector layer; and
forming a memory cell including a memory pattern and a selector pattern by etching the memory layer and the selector layer through an etching process using a mask pattern.

8. The method of claim 7, further comprising:
at least one of forming a first electrode layer between the substrate and the selector layer or between the substrate and the memory layer;
forming a second electrode layer between the selector layer and the memory layer; and
forming a third electrode layer in an upper portion of the memory layer or in the upper portion of the selector layer.

9. The method of claim 7, wherein forming the carbon layer includes a physical deposition process.

10. The method of claim 7, wherein forming the carbon layer is performed in a gas atmosphere of at least one of nitrogen gas, oxygen gas, and hydrogen gas.

11. The method of claim 7, wherein forming the carbon layer is performed to form an amorphous carbon layer.

12. The method of claim 7, wherein the ion implantation process is performed using a dopant including at least one of arsenic (As), phosphorus (P), and antimony (Sb).

13. The method of claim 7, wherein a defect or vacancy is formed in the selector layer by implanting the dopant.
